(19) United States
(12) Patent Application Publication
(10) Pub. No.: US 2026/0181971 A1
(43) Pub. Date: Jun. 25, 2026

(54) SEMICONDUCTOR DEVICES WITH FIELD RELIEF DIELECTRIC STRUCTURES

(71) Applicant: Texas Instruments Incorporated, Dallas, TX (US)

(72) Inventors: Archana Venugopal, Mountain View, CA (US); Casey Hopper, Richardson, TX (US)

(21) Appl. No.: 18/999,904

(22) Filed: Dec. 23, 2024

Related U.S. Application Data
(60) Provisional application No. 63/738,085, filed on Dec. 23, 2024.

(51) Int. Cl. H10D 62/10; H01L 21/762; H10D 30/01; H10D 30/65

(52) U.S. Cl. CPC H10D 62/102; H10D 30/0281; H10D 30/65; H10W 10/0124; H10W 10/014; H10W 10/13; H10W 10/17

(57) ABSTRACT

Semiconductor devices and fabrication methods thereof are described. For example, a semiconductor device includes a source region and a drain region spaced apart in a semiconductor layer, a gate dielectric layer on a top surface of the semiconductor layer and extending from the source region toward the drain region, and a field relief dielectric structure over the semiconductor layer and extending from the gate dielectric layer toward the drain region. The field relief dielectric structure includes a dielectric layer and a local oxidation of silicon (LOCOS) layer between the dielectric layer and the semiconductor layer, the LOCOS layer extending below the top surface of the semiconductor layer by no more than 10 nanometers.

### RELATED APPLICATION

The present application claims benefit of and priority to U.S. Provisional Application Ser. No. 63/738,085, filed on Dec. 23, 2024, which is incorporated by reference herein.

### TECHNICAL FIELD

The present disclosure relates to the field of integrated circuits, and more particularly, but not exclusively, to transistors such as laterally diffused metal oxide semiconductor (LDMOS) transistors.

### BACKGROUND

LDMOS devices are field-effect transistors (FETs) that are applicable to high power applications. In an LDMOS device, the drain and source have a relatively large spacing between them, as compared with metal oxide semiconductor (MOS) devices designed for other applications such as logic functions, and lateral diffusions are used to produce a well-controlled drift region from the channel region to the drain. The operational performance of LDMOS devices is generally affected by parameters including, for example, a specific on-resistance (Rsp) and a breakdown voltage (BV). One design goal of LDMOS devices is to decrease Rsp and increase BV, or at least to improve one parameter without adversely affecting the other parameter.

### SUMMARY

The present disclosure describes semiconductor devices with field relief dielectric structures and methods of fabrication thereof. This summary is not an extensive overview of the disclosure. Rather, a purpose of the summary is to present some examples of the present disclosure in a simplified form as a prelude to a more detailed description that is presented later.

In some examples, a method of fabricating an integrated circuit includes forming a drain region in a semiconductor layer, the drain region including a drain drift region, and forming a local oxidation of silicon (LOCOS) layer over the drain drift region, the LOCOS layer having a bird's-beak region having a thickness that decreases from a maximum thickness of the LOCOS layer to a lesser thickness. The method also includes forming a field relief dielectric layer over the LOCOS layer, the field relief dielectric layer having a sloped sidewall over the bird's beak region, and forming a gate electrode over the field relief dielectric layer.

In some other examples, a method of fabricating a semiconductor device includes forming a source region and a drain region spaced apart in a semiconductor layer, forming a gate dielectric layer over the semiconductor layer and extending from the source region toward the drain region, and forming a field relief dielectric structure over the semiconductor layer and extending from the gate dielectric layer toward the drain region. The field relief dielectric structure includes a dielectric layer and a LOCOS layer between the dielectric layer and the semiconductor layer, the LOCOS layer extending below the top surface of the semiconductor layer by no more than 10 nanometers.

In some other examples, a semiconductor device includes a source region and a drain region spaced apart in a semiconductor layer, a gate dielectric layer on a top surface of the semiconductor layer and extending from the source region toward the drain region, and a field relief dielectric structure over the semiconductor layer and extending from the gate dielectric layer toward the drain region. The field relief dielectric structure includes a dielectric layer and a LOCOS layer between the dielectric layer and the semiconductor layer, the LOCOS layer extending below the top surface of the semiconductor layer by no more than 10 nanometers.

### BRIEF DESCRIPTION OF THE DRAWINGS

FIG. 1 is a cross-sectional view of a semiconductor device having a field relief dielectric structure including a local oxidation of a silicon (LOCOS) layer and a dielectric layer deposited over the LOCOS layer in accordance with an example of the present disclosure;

FIG. 2 is a cross-sectional view of another semiconductor device having a field relief dielectric structure including a LOCOS layer and a dielectric layer deposited over the LOCOS layer in accordance with an example of the present disclosure;

FIGS. 3A-3N are cross-sectional views of a method of fabricating a semiconductor device having a field relief dielectric structure including a LOCOS layer and a dielectric layer deposited over the LOCOS layer in accordance with an example of the present disclosure.

FIG. 4 is a cross-sectional view of another semiconductor device having a field relief dielectric structure including a LOCOS layer and a dielectric layer deposited over the LOCOS layer in accordance with an example of the present disclosure; and

FIG. 5 is a cross-sectional view of another semiconductor device having a field relief dielectric structure including a LOCOS layer and a dielectric layer deposited over the LOCOS layer in accordance with an example of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about” or “approximately,” preceding a value mean +/−10-20 percent of the stated value. The terms “substantially” or “substantially equal” means values within +2.5% of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the operational performance of an LDMOS device is generally affected by a tradeoff between a specific on-resistance (Rsp) or a drain-source on-resistance (Rdson) parameter and a breakdown voltage (BV) parameter. For example, design approaches that seek to achieve the advantage of a higher BV by increasing the body area of the device consequently lead to the disadvantage of a higher Rsp. Similarly, design approaches that seek to decrease Rsp generally come at the cost of decreasing the BV rating. Accordingly, LDMOS design approaches that effectively manage this tradeoff provide technical advantages.

LDMOS or other power devices may be designed for high voltage and/or high current operation, such as in power management applications. Achieving a better Rdson versus BV tradeoff for high voltage components is an important aspect of device performance.

Semiconductor devices, such as drain extended transistor devices, are described herein which allow for improved device performance (e.g., a reduced Rdson and/or greater BV) through the introduction of a field relief dielectric structure including a first portion formed using a local oxidation of silicon (LOCOS) process and a second portion which is deposited over the LOCOS-formed first portion. The LOCOS process is advantageously designed to provide a controlled, well-engineered taper and transition from a thickness of a gate dielectric layer to the field relief dielectric structure in order to limit a high electric field at the transition edge (e.g., from the gate dielectric to the field relief dielectric structure) being a BV limiter. Drain extended transistors can include drain-extended NMOS (DENMOS), drain-extended PMOS (DEPMOS), and/or laterally diffused MOS (LDMOS) transistors, as well as groups of DENMOS and DEPMOS, referred to as complimentary drain extended MOS or DECMOS transistors. While examples of the disclosure may be expected to provide improvements such as described, no particular result is a requirement of the present invention unless explicitly recited in a particular claim.

The field relief dielectric structure, in some examples, is formed using a two-step process wherein a first portion is formed using a LOCOS process and a second portion is deposited or grown over the first portion. The first portion of the field relief dielectric structure may be referred to as a LOCOS-grown layer or LOCOS layer, while the second portions of the field relief dielectric structure may be referred to as a deposited field relief layer. The first portion of the field relief dielectric structure is a LOCOS-grown layer with a limited thickness (e.g., less than 20 nanometers (nm), less than 10% of the thickness of shallow trench isolation (STI) structures, etc.) that creates a bird's beak edge at a transition region between a gate dielectric layer and the field relief dielectric structure. The LOCOS process used to form the first portion of the field relief dielectric structure advantageously extends into or consumes very little of the underlying silicon, approximately maintaining the planar characteristics of the drift region between a drain region and a channel region. The second portion of the field relief dielectric structure is deposited or grown over the LOCOS layer, and may be thicker (e.g., at least twice as thick) as the LOCOS layer. The second portion of the field relief dielectric structure, in some examples, has tapered sidewalls for further controlling the taper and transition from the thickness of the gate dielectric layer to the field relief dielectric structure. The first portion of the field relief dielectric structure, being formed using a LOCOS process, is an oxide material. The second portion of the field relief dielectric structure, may be any suitable dielectric material, including an oxide, a nitride, an oxide-nitride-oxide (ONO) multi-layer, a high-k dielectric, etc.

In some examples, a method of fabricating an integrated circuit includes forming a drain region in a semiconductor layer, the drain region including a drain drift region, and forming a LOCOS layer over the drain drift region, the LOCOS layer having a bird's-beak region having a thickness that decreases from a maximum thickness of the LOCOS layer to a lesser thickness. The method also includes forming a field relief dielectric layer over the LOCOS layer, the field relief dielectric layer having a sloped sidewall over the bird's beak region, and forming a field plate over the field relief dielectric layer. The field relief dielectric layer may be silicon nitride (SiN), silicon oxide (SiOₓ), at least one oxide layer and at least one nitride layer, etc. The field relief dielectric layer may have a relative dielectric permittivity of at least 4. The sloped sidewall of the field relief dielectric layer may meet the LOCOS layer over the bird's beak region. The sloped sidewall of the field relief dielectric layer may form an angle with a top surface of the semiconductor layer of no greater than 80°. The LOCOS layer may have a first thickness and the field relief dielectric layer may have a second thickness, the second thickness being at least twice the first thickness.

In other examples, a method of fabricating a semiconductor device includes forming a source region and a drain region spaced apart in a semiconductor layer, forming a gate dielectric layer over the semiconductor layer and extending from the source region toward the drain region, and forming a field relief dielectric structure over the semiconductor layer and extending from the gate dielectric layer toward the drain region. The field relief dielectric structure includes a dielectric layer and a LOCOS layer between the dielectric layer and the semiconductor layer, the LOCOS layer extending below a top surface of the semiconductor layer by no more than 10 nanometers. The dielectric layer may be a nitride material, an oxide material, combinations thereof, etc. A sidewall of the dielectric layer (e.g., a sidewall of the dielectric layer that extends towards the gate dielectric layer) may have a tapered profile. The method may also include forming an STI structure surrounding the semiconductor device, where the LOCOS layer has a thickness no greater than 10% a thickness of the STI structure. The semiconductor device may be an LDMOS transistor.

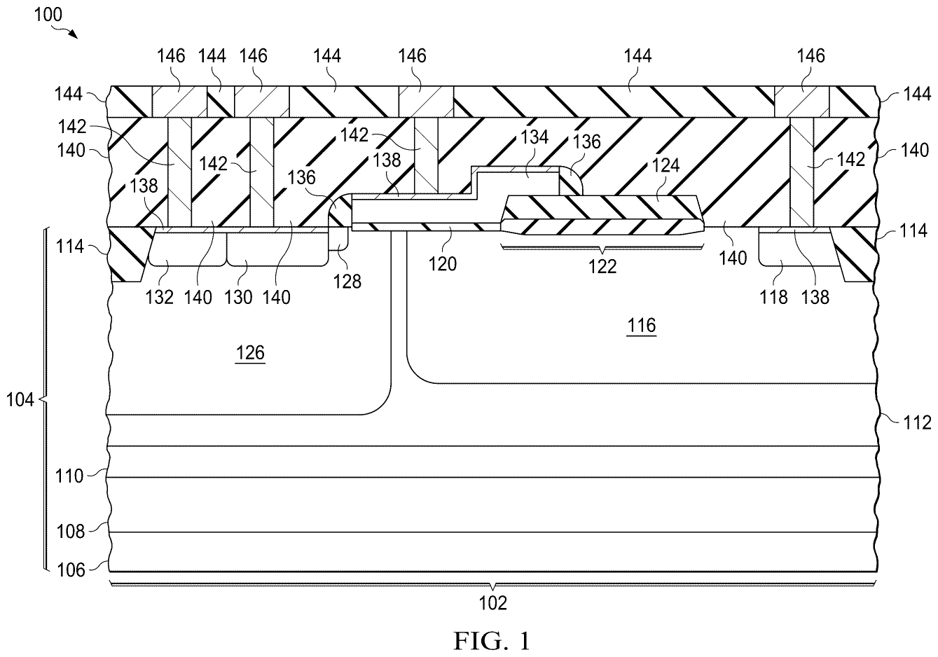

Referring now to FIG. 1, a cross-sectional view of a microelectronic device 100, e.g., an integrated circuit (IC), is shown. The microelectronic device 100 includes an LDMOS transistor 102. FIG. 1 shows an example where the LDMOS transistor 102 is an n-channel device. It should be appreciated, however, that an analogous p-channel device may be formed with appropriate substitution of p-type regions for n-type regions and vice versa. The LDMOS transistor 102 is located in and over an epitaxial layer 104 over a substrate (not shown). The epitaxial layer 104 may be formed initially as a lightly-doped p-type layer, from which other regions of the LDMOS transistor 102 are formed by additional suitable doping. The semiconductor material of the epitaxial layer 104 is not limited to any particular material, but is described herein as silicon without implied limitation. The LDMOS transistor 102 includes an optional n-type buried layer (NBL) 108 and an optional p-type buried layer (PBL) 110. A “buried layer” is defined as a layer having a first doping characteristic, e.g. conductivity type, dopant type or dopant concentration, spaced apart from a top surface of the epitaxial layer 104 by another layer having a different second doping characteristic, and having a lateral extent parallel to the top surface that is greater than a thickness of the layer having the first doping characteristic. An un-modified portion 106 of the epitaxial layer 104 is located between the NBL 108 and the substrate, and an un-modified portion 112 of the epitaxial layer 104 is located between the PBL 110 and a top surface of the epitaxial layer 104. The un-modified portion 112 of the epitaxial layer 104 may also referred to herein as lightly doped region 112 or p-epi region 112.

Shallow trench isolation (STI) structures 114 are formed in isolation trenches formed in the epitaxial layer 104, and may be primarily silicon dioxide (SiO₂) or a SiO₂-based dielectric material formed by one or more chemical vapor deposition (CVD) processes alternated with etch-back processes to provide complete filling of the isolation trenches.

An n-type drift (NDRIFT) region 116 and a p-type DWELL region 126 are formed in the epitaxial layer 104 between the PBL 110 and the top surface of the epitaxial layer 104. The p-type DWELL region 126 may operate as a body region of the LDMOS transistor 102, and the NDRIFT region 116 may operate as an extended drift region of the LDMOS transistor 102. Within the NDRIFT region 116 is a drain region 118 and a portion of the STI structures 114. Within the p-type DWELL region 126 is an n-type source extension 128, a source region 130, a back gate or body contact region 132 and another portion of the STI structures 114. The drain region 118 and the source region 130 are n-type, and the back gate or body contact region 132 is p-type.

A gate dielectric layer 120 is located over a junction between the NDRIFT region 116 and the p-type DWELL region 126. The gate dielectric layer 120 extends over the junction from the n-type source extension 128 to a LOCOS layer 122. In the example shown in FIG. 1, the gate dielectric layer 120 is thinner than the LOCOS layer 122. As will be described in further detail below, however, the gate dielectric layer 120 in other examples may have substantially the same thickness as the LOCOS layer 122, or may be thicker than the LOCOS layer 122. A field relief dielectric layer 124 is formed over the LOCOS layer 122. The LOCOS layer 122 and the field relief dielectric layer 124 collectively provide what is referred to herein as a field relief dielectric structure. As shown in FIG. 1, the field relief dielectric layer 124 has sloped sidewalls, which together with a tapered portion of the LOCOS layer 122 (e.g., which tapers from a maximum thickness to a smaller thickness proximate the gate dielectric layer 120) advantageously provides smoothing of the electric field transition for the LDMOS transistor 102 near the end of the LOCOS layer 122 nearest the source region 130.

An electrode 134 extends from the source region130 toward the drain region 118 over the gate dielectric layer 120 and partially over the field relief dielectric layer 124. The electrode 134 may be referred to as a gate electrode 134, but where distinction is useful in the description the portion of the electrode 134 over the field relief dielectric layer 124 may be referred to as a field plate 134.

Dielectric sidewall spacers 136 cover sidewalls of the gate electrode 134. The dielectric sidewall spacers 136 are also referred to herein as gate spacers or gate sidewall spacers 136.

Silicide layers 138 form ohmic electrical connections to the drain region 118, the source region 130, the back gate or body contact region 132 and the gate electrode 134. The silicide layers 138 may also be referred to as metal silicide layers 138. A pre-metal dielectric (PMD) layer 140 covers the structure, and contacts 142 extend vertically from the silicide layers 138 to interconnects 146 separated by portions of an inter-metal dielectric (IMD) layer 144.

A method of forming the microelectronic device 100 including the LDMOS transistor 102 will now be described. As noted above, the LDMOS transistor 102 is shown as being n-channel. An analogous p-channel LDMOS transistor can be formed by substituting n-toped regions with p-doped regions and vice versa. In the case of an n-channel LDMOS transistor, a p-type region may be described as having a “first conductivity type” and an n-type region may be described as having a “second conductivity type.” Likewise, in the case of a p-channel LDMOS transistor, an n-type region may be described as having a first conductivity type and a p-type region may be described as having a second conductivity type.

The microelectronic device 100 includes a substrate including the epitaxial layer 104. The epitaxial layer 104 may, for example, by formed over a bulk semiconductor wafer, a silicon-on-insulator (SOI) wafer, or other structure suitable. A base wafer may be p-type with a dopant concentration of about 10¹⁷ atoms/cm³ to 10¹⁸ atoms/cm³. Alternatively, the base wafer may be lightly doped, meaning the base wafer has an average dopant concentration below 10¹⁶ atoms/cm³.

The optional NBL 108 is formed within the epitaxial layer 104. The NBL 108 may be about 2 to 10 micrometers (μm) thick, and may have a dopant concentration of about 10¹⁷ atoms/cm³ to 10¹⁸ atoms/cm³. The lightly doped region 112 (prior to formation of the PBL 110 as discussed below) extends from the NBL 108 to the top surface of the epitaxial layer 104. The lightly doped region 112 may be about 2 to 12 μm thick. The lightly doped region 112 is p-type in the example in which the LDMOS transistor 102 is an n-channel device, and may have a dopant concentration of about 10¹⁵ atoms/cm³ to 10¹⁶ atoms/cm³. In versions where the optional NBL 108 is omitted, the un-modified portion 106 of the epitaxial layer is an extension of the lightly doped region 112.

A pad oxide layer (not specifically shown) of SiO₂ may be formed on the lightly doped region 112. The pad oxide layer may include SiO₂ that is formed by a thermal oxidation process or a CVD process. The pad oxide layer may provide stress relief between the lightly doped region 112 and subsequent layers. The pad oxide layer may be about 5 to 50 nm thick. A chemical mechanical planarization (CMP) stop layer may then be deposited, followed by formation of a mask layer. The CMP stop layer may be SiN or another material with a high selectivity for CMP of oxide materials. The mask layer serves the function of masking the CMP stop layer, and may be formed of a photoresist material and thus referred to as a photomask. The photomask may include a light sensitive organic material that is coated, exposed and developed. After formation and patterning of the mask layer, a plasma etch process is used to remove the CMP stop layer, the pad oxide layer and a portion of the lightly doped region 112 to form isolation trenches. The isolation trenches may be about 250 nm to 1 μm in depth.

The STI structures 114 are formed in the isolation trenches and over the CMP stop layer. The STI structures 114, as noted above, may include primarily SiO₂ or a SiO₂-based dielectric material that is formed by one or more CVD processes alternated with etch-back processes to provide complete filling of the isolation trenches. The STI structures 114 are planarized so that they do not extend over the top surface of the epitaxial layer 104. After the STI structures 114 are planarized, the CMP stop layer is removed. The CMP stop layer may be removed by a wet etch process using an aqueous solution of phosphoric acid at about 140° C. to 170° C. The pad oxide layer may optionally be removed by a wet etch process using an aqueous solution of buffered hydrofluoric acid.

A mask layer is then deposited and patterned in a region where a drift region implant is used to form the NDRIFT region 116 within exposed areas of the lightly doped region 112. The drift region implant may implant an n-type dopant in one or more steps. In some examples, phosphorus is implanted by multiple steps (e.g., a chain implant) resulting in a total dose of between about 3×10¹² cm⁻² and 6.6×10¹² cm⁻² with energies between about 0.5 mega-electron volts (MeV) and 2.8 MeV. In some examples, arsenic is also implanted at an energy of between about 180 kilo-electron volts (keV) to 460 keV with a dose of between about 1.5×10¹² cm⁻² and 3.0×10¹². All of the implant processes may use the same mask layer to complete the formation of the NDRIFT region 116.

The PBL 110 may then be formed, if used, for example, using a high energy p-type implant (a PBL implant) to add doping to the lightly doped region 112. The PBL implant can comprise boron at a dose from about 3×10¹² cm⁻² to 5×10¹² cm⁻² at an energy of between about 1.7 MeV and 3 MeV. Indium may also be used as the implant species. For low voltage (e.g., 20 V) versions of the LDMOS transistor 102, the PBL implant can be a blanket implant, while for higher voltage (e.g., >30 V) versions of the LDMOS transistor 102, the PBL implant may be a masked implant to allow selective placement.

After the wafer is cleaned, an implant mask is formed over the microelectronic device to expose an area where the p-type DWELL region 126 is to be formed. A DWELL implant process implants p-type dopants into a portion of the lightly doped region 112 laterally adjacent to the NDRIFT region 116, including at least a first well ion implant comprising a p-type dopant to form the p-type DWELL region 126. The p-type dopants implanted by the DWELL implant process may include boron. Besides boron, the p-type dopants can include indium. Indium, being a relatively large atom, has the advantage of a low diffusion coefficient relative to boron. In the case of a boron implant, the DWELL implant process can be similar in energy to energies used to form n-type source/drain regions or n-type lightly doped drain regions in the epitaxial layer 104, and the dose used should generally be sufficient to enable formation of a channel laterally and to suppress body NPN effects during operation of the LDMOS transistor 102. For example, a series of boron implants with an energy between about 80 keV and 3 MeV, and doses between about 4.0×10¹² cm⁻² to 1.5×10¹⁴ cm⁻², with a tilt angle of less than 10 degrees may be used to implant the p-type DWELL region 126. A rapid thermal process (RTP) may be used to activate dopants in the p-type DWELL region 126.

A pad oxide layer is formed over a top surface of the epitaxial layer 104, followed by patterning a mask layer over the pad oxide layer. The pad oxide layer may be formed by an oxidation process that may be implemented by a high temperature furnace operation or a rapid thermal process. The thickness of the pad oxide layer may range from about 3 nm to 15 nm. Portions of the pad oxide layer exposed by the mask layer (e.g., in an area where the LOCOS layer 122 is to be formed) are then at least partially removed, followed by a LOCOS process which forms the LOCOS layer 122. As will be described in further detail below, the LOCOS process is configured such that the LOCOS layer 122 has a relatively small thickness (e.g., in some examples, extending no more than 10 nm below the top surface of the epitaxial layer 104, having a thickness that is 10% or less than the thickness of the STI structures 114, etc.). The LOCOS process forms a bird's beak profile, which advantageously smooths the electric field transition in the LDMOS transistor 102. The field relief dielectric layer 124 is then deposited over the LOCOS layer 122, followed by planarization (e.g., using chemical mechanical planarization (CMP) or other suitable processing) and subsequent removal of the mask layer. The field relief dielectric layer 124 may have a thickness that is at least twice the thickness of the LOCOS layer 122. To form the sloped sidewalls of the field relief dielectric layer 124, an additional mask layer may be patterned to cover the field relief dielectric layer 124, followed by an etch process which forms the sloped sidewalls and subsequent removal of the mask layer. The pad oxide layer may then be removed, followed by formation of the gate dielectric layer 120.

The gate electrode 134 is then formed over the gate dielectric layer 120 and the field relief dielectric layer 124. The gate electrode 134, in some examples, includes polysilicon and may be deposited by a gate deposition process that may use a silane-based reagent. In other examples, the gate electrode 134 may be formed by a metal gate or CMOS-based replacement gate electrode process. A mask layer is deposited and patterned over an electrode material layer, e.g. polysilicon. A plasma etch process defines the gate electrode 134, removing portions of the electrode material layer. The gate dielectric layer 120 extends from the LOCOS layer 122 and over the p-type DWELL region 126.

A pattern and implant step using an n-type dopant such as arsenic or antimony may be used to form the n-type source extension 128. In some examples, arsenic with a dose between about 6.0×10¹³ cm⁻² and 8.0×10¹⁵ cm⁻² with an energy between about 60 to 120 keV with a tilt angle of between 0 degrees and 45 degrees may be used for the n-type source extension 128 dopant. An arsenic energy of greater than 15 keV can allow the arsenic to penetrate through the gate dielectric layer 120 (e.g., when a 5 V oxide is used for gate dielectric) adjacent to the gate electrode 134, which makes a lighter doped region under the future sidewall spacer to make a good connection between the source/drain and the inverted channel in the device for improved hot carrier performance. The arsenic implant may be implanted at an angle, thereby reducing the channel voltage threshold (Vt) without reducing the p-type DWELL region 126 implant dose, enabling the simultaneous improvement of Vt and control of the body doping of the parasitic NPN. Additionally, the arsenic dose may be made in more than one step to put most of the arsenic dose in the vertical implant and the rest into the angled implant.

After formation of the n-type source extension 128, the dielectric sidewall spacers 136 are formed on sidewalls of the gate electrode 134. The dielectric sidewall spacers 136 may be formed by forming one or more conformal layers of dielectric material over the top surface of the epitaxial layer 104 and the gate electrode 134. The dielectric material is subsequently removed from horizontal surfaces, that is, surfaces generally parallel to the top surface of the epitaxial layer 104, by an anisotropic etch process such as an RIE process, leaving the dielectric material on the lateral surfaces of the gate electrode 134. The dielectric sidewall spacers 136 may include one or more dielectric materials such as SiO₂, SiN, etc. The dielectric sidewall spacers 136 may extend about 100 nm to 500 nm from the lateral surfaces of the gate electrode 134.

The drain region 118, the source region 130 and the back gate or body contact region 132 are then formed. One or more patterning and ion implantation steps are used to implant the drain region 118 in the NDRIFT region 116, and to implant the source region 130 and the back gate or body contact region 132 in the p-type DWELL region 126. The drain region 118 and the source region 130 implantation may occur in one or more steps with implant species including one or more of phosphorus and arsenic with an overall dose of between about 5×10¹³ cm⁻² and 4.5×10¹⁵ cm⁻² and an energy between about 2 keV and 80 keV. The drain region 118 contains an average dopant density many times higher than that of the NDRIFT region 116.

A silicide block layer may be formed by depositing one or more sublayers of an oxide material, a nitride material, an oxynitride material or any combination thereof over the top surface of the epitaxial layer 104. The silicide block layer is then patterned using a mask layer and removed using a RIE etch process in regions where the silicide layers 138 are to be formed. The silicide block layer is allowed to remain in areas where the silicide layers 138 are not intended to be formed. In some examples, the silicide block layer is not required and may be omitted. A metal layer which forms a metal silicide at temperatures consistent with typical semiconductor manufacturing process conditions is then deposited on the wafer surface, and the microelectronic device 100 is heated to form the silicide layers 138 in exposed areas of the lightly doped region 112 and the gate electrode 134. Unreacted metal is subsequently removed in a wet stripping process.

After the silicide layers 138 are formed, the PMD layer 140 is formed. The PMD layer 140 may include a PMD liner (not specifically shown) over the microelectronic device 100. The PMD liner may be formed of a SiN, SiON, SiO₂, etc. The main dielectric sublayer of the PMD layer 140 is formed over the PMD liner, if present. The main dielectric sublayer of the PMD layer 140 may be formed by one or more dielectric deposition processes, including a PECVD process using TEOS, a high-density plasma (HDP) process, or a high aspect ratio process (HARP) using TEOS and ozone. The PMD layer 140 may be planarized by an oxide CMP process.

The contacts 142 may be formed by patterning and etching holes through the PMD layer 140 (and the PMD liner, if present) to expose portions of the silicide layers 138. The contacts 142 are filled in such holes, in some examples, by sputtering titanium or another suitable material to form a metal adhesion layer, followed by forming a titanium nitride (TiN) or other suitable diffusion barrier using reactive sputtering or an atomic layer deposition (ALD) process. A tungsten plug may then be formed by an MOCVD process using tungsten hexafluoride (WF₆) reduced by silane initially and hydrogen after a layer of tungsten is formed on the TiN diffusion barrier. The tungsten, TiN, and titanium are subsequently removed from a top surface of the PMD layer 140 by a plasma etch process, a tungsten CMP process, or a combination of both, leaving the contacts 142 extending to the top surface of the PMD layer 140. In some examples, the contacts 142 may be formed by a selective tungsten deposition process which fills the contacts 142 with tungsten from the bottom up, forming the contacts 142 with a uniform composition of tungsten.

The interconnects 146 are then formed on the contacts 142. In some examples, the interconnects 146 have an etched aluminum structure, and may be formed by depositing an adhesion layer, an aluminum layer and an anti-reflection layer, and forming an etch mask followed by an RIE process to etch the anti-reflection layer, the aluminum layer and the adhesion layer where exposed by the etch mask, and subsequently removing the etch mask. In other examples, the interconnects 146 have a damascene structure, and may be formed by forming the IMD layer 144 on the PMD layer 140 and etching interconnect trenches through the IMD layer 144 to expose the contacts 142. A barrier liner (not shown) may be formed by sputtering tantalum onto the IMD layer 144, the PMD layer 140 and the contacts 142 which are exposed, and then forming tantalum nitride (TaN) on the sputtered tantalum by an ALD process. A copper fill metal may be formed by sputtering a seed layer (not shown) of copper on the barrier liner, and electroplating copper on the seed layer to fill the interconnect trenches. The copper and barrier liner metal are subsequently removed from a top surface of the IMD layer 144 by a copper CMP process. In other examples, the interconnects 146 have a plated structure, and may be formed by sputtering an adhesion layer, containing titanium, on the PMD layer 140 and the contacts 142, followed by sputtering a seed layer of copper on the adhesion layer. A plating mask is formed on the seed layer that exposes areas for the interconnects 146. The interconnects 146 are then formed by electroplating copper on the seed layer where exposed by the plating mask. The plating mask is removed, and the seed layer and the adhesion layer are removed by wet etching between the interconnects 146.

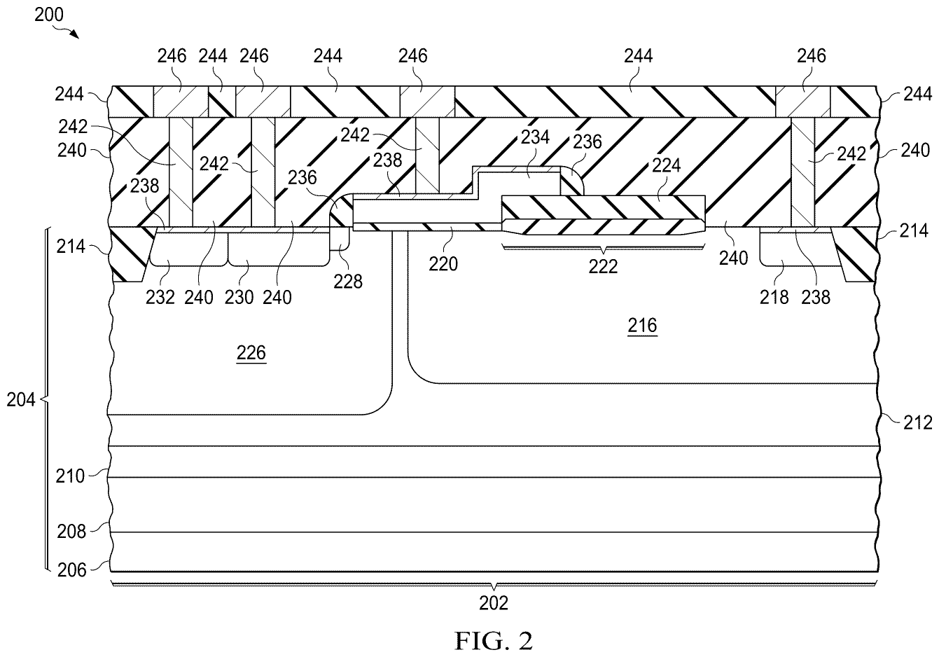

Referring now to FIG. 2, a cross-sectional view of a microelectronic device 200 is shown. The microelectronic device 200 includes LDMOS transistor 202, epitaxial layer 204, un-modified portion 206 of the epitaxial layer 204, optional NBL 208, optional PBL 210, un-modified portion 212 of the epitaxial layer 204, STI structures 214, NDRIFT region 216, drain region 218, gate dielectric layer 220, LOCOS layer 222, field relief dielectric layer 224, p-type DWELL region 226, n-type source extension 228, source region 230, back gate or body contact region 232, gate electrode 234, dielectric sidewall spacers 236, silicide layers 238, PMD layer 240, contacts 242, IMD layer 244 and interconnects 246. These features are analogous to those shown in the microelectronic device 100. However, whereas the field relief dielectric layer 124 of the microelectronic device 100 has sloped sidewalls, the field relief dielectric layer 224 of the microelectronic device 200 has straight or non-sloped sidewalls. It should be noted that having the straight or non-sloped sidewalls may result in a sharper electric field transition in the LDMOS transistor 202 (relative to the LDMOS transistor 102) due to corner effects, though this is partially mitigated due to the bird's beak profile of the underlying LOCOS layer 222. While the sloped sidewalls of the field relief dielectric layer 124 in the LDMOS transistor 102 (FIG. 1) may provide favorable reduction of maximum electric field strength relative to the field relief dielectric layer 224, the field relief dielectric layer 224 reduces process complexity, which may provide other advantages in some implementations.

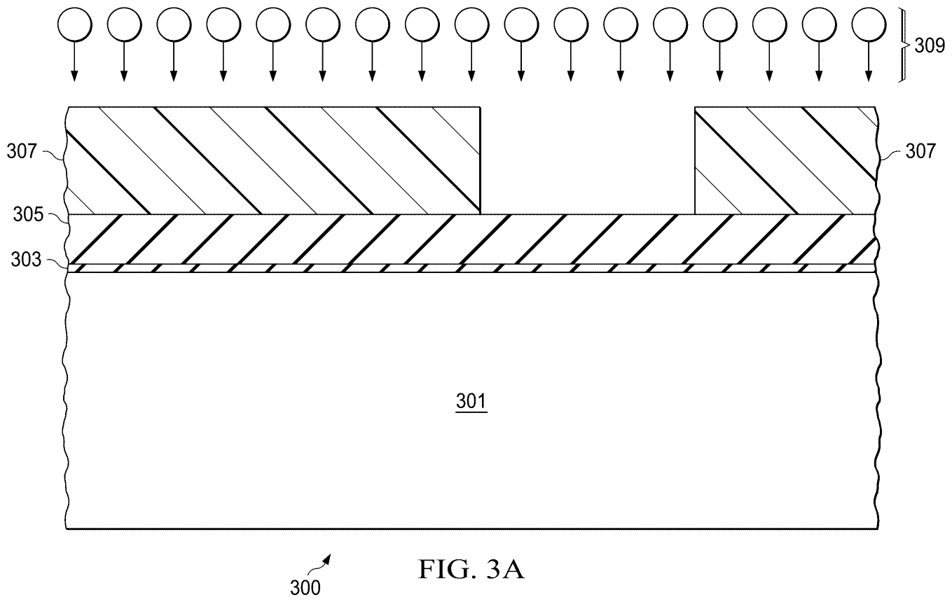

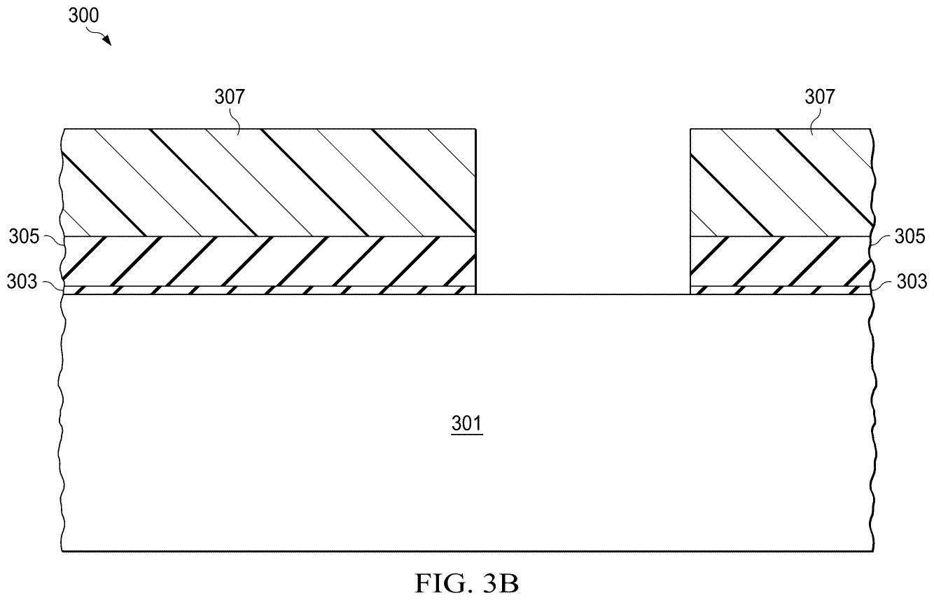

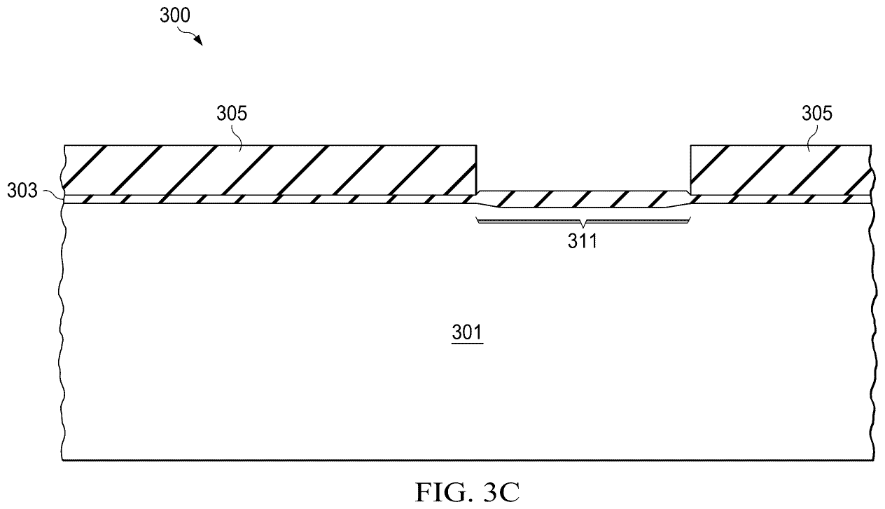

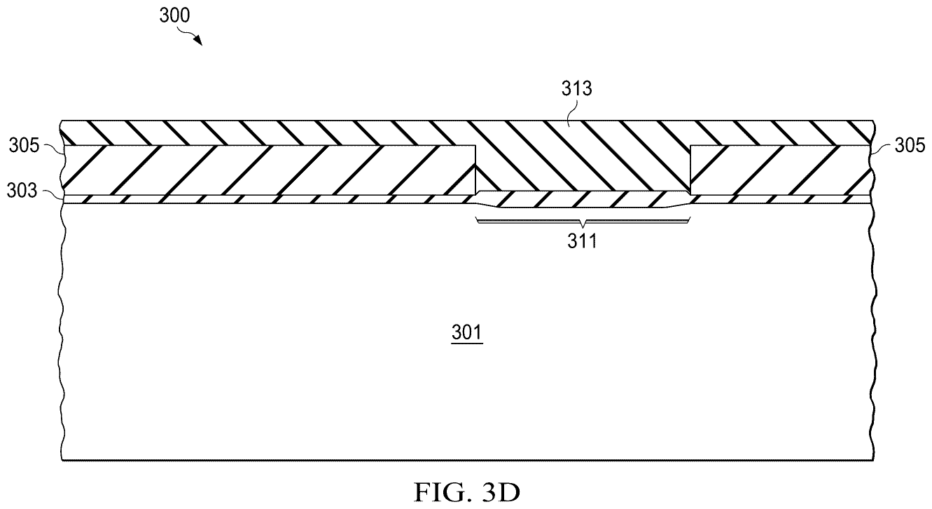

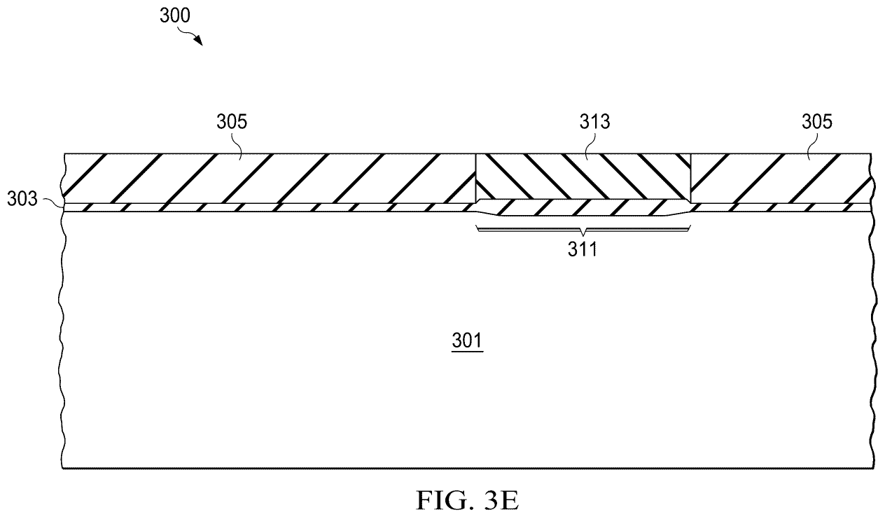

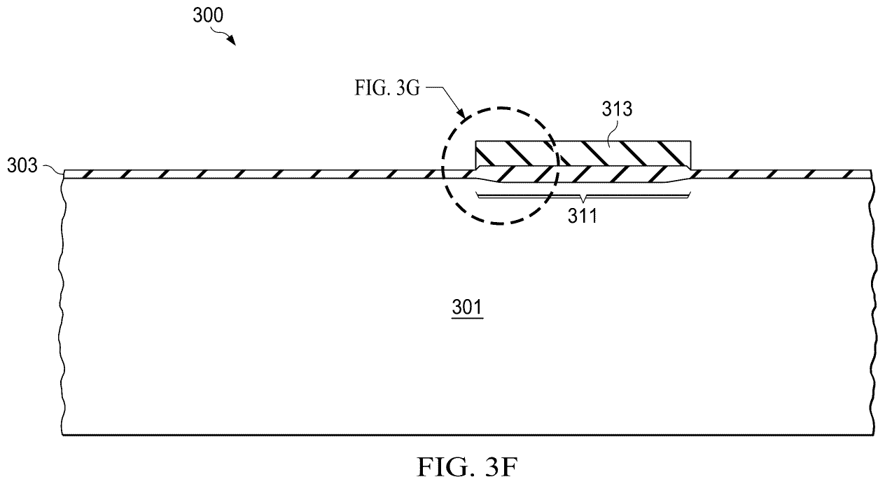

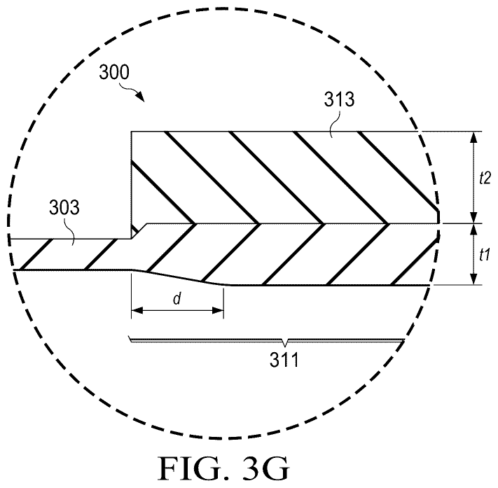

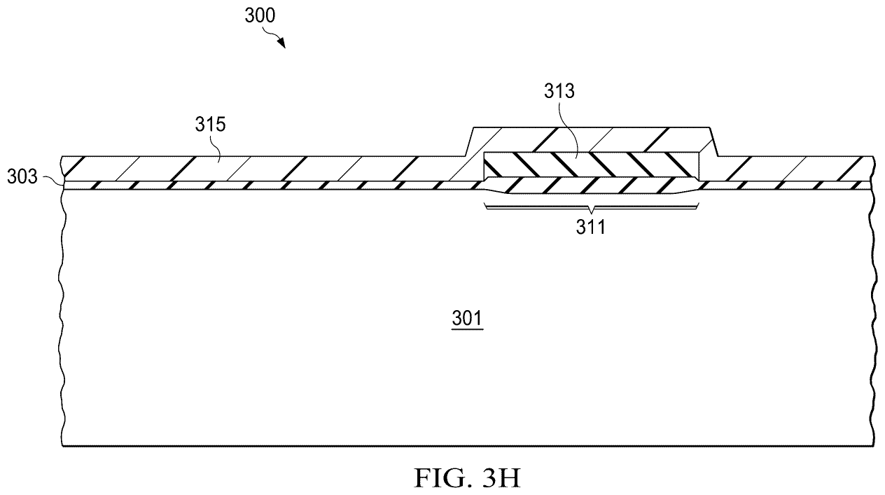

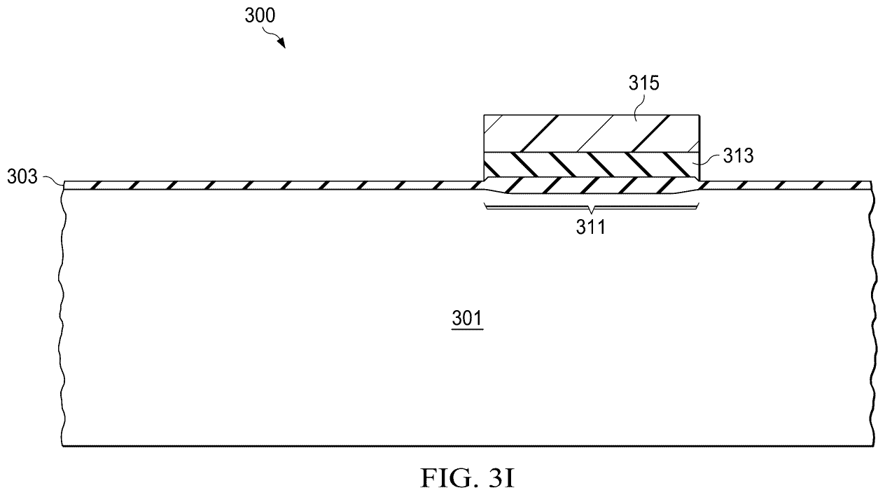

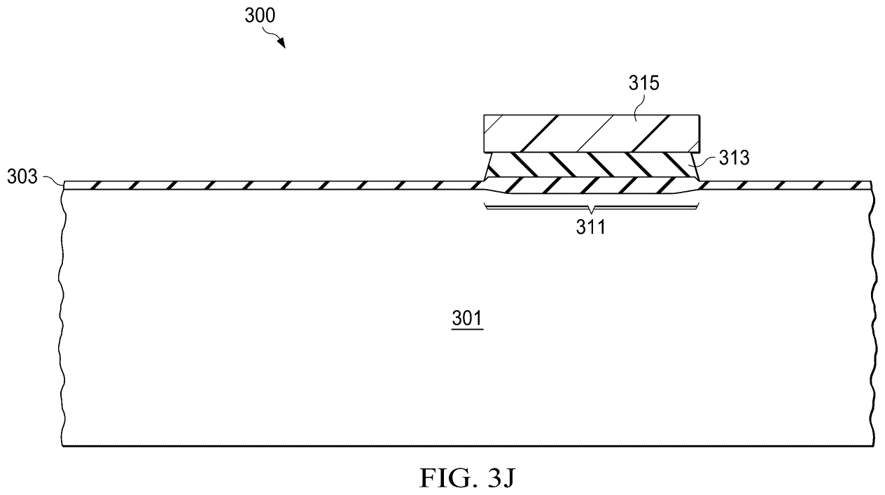

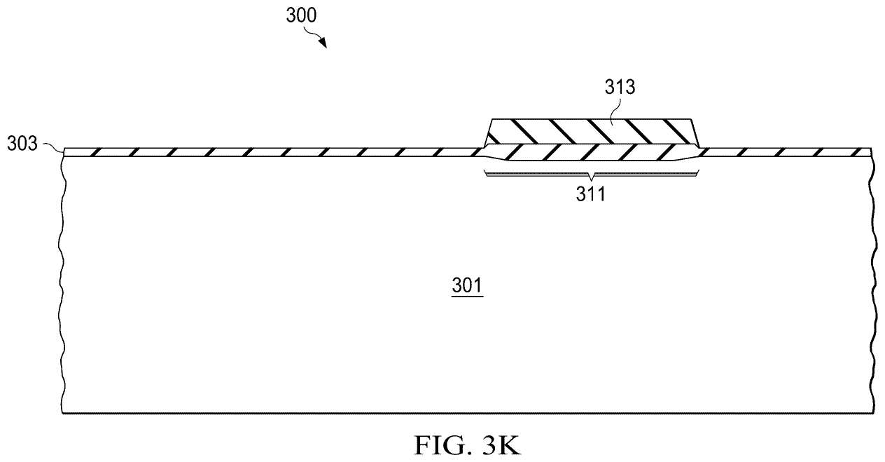

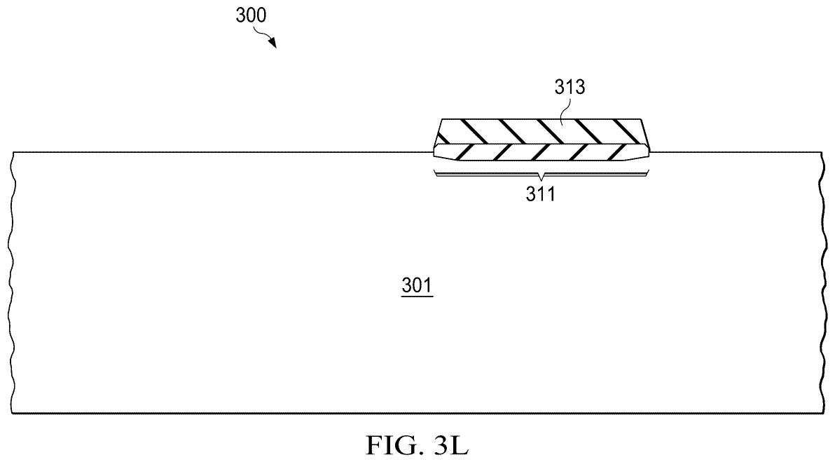

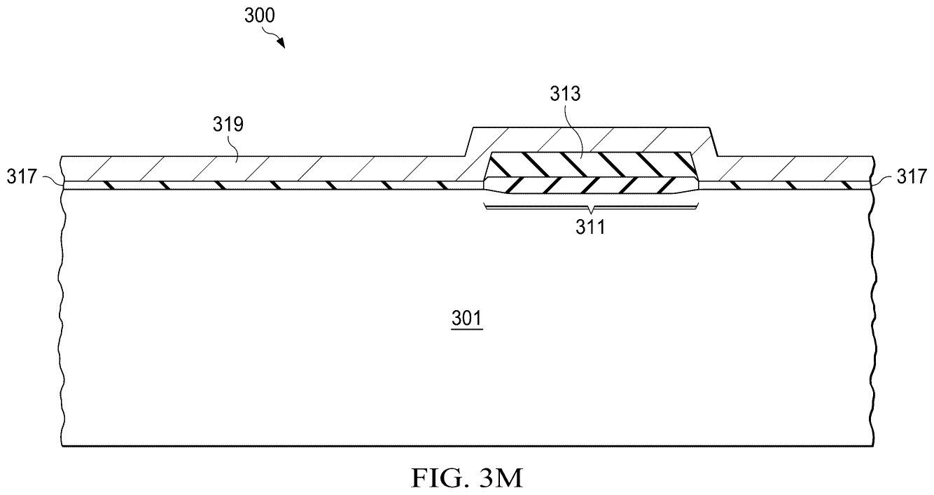

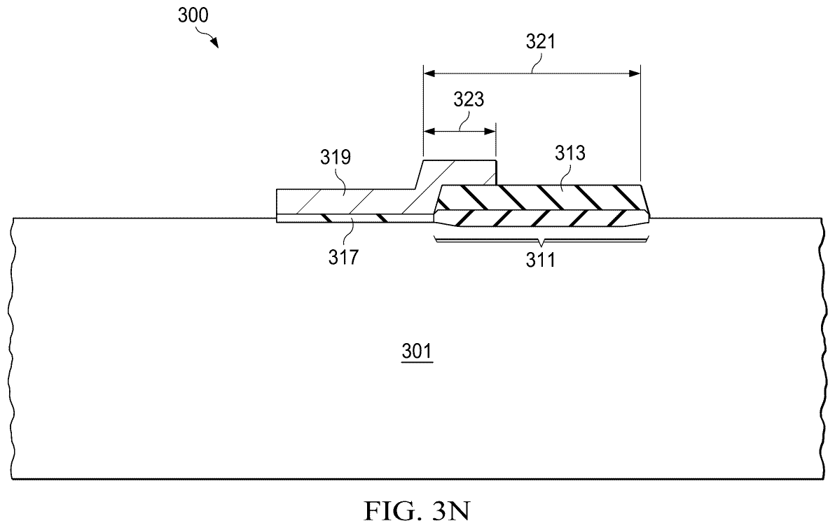

Referring now to FIGS. 3A-3N, cross-sectional views of a process flow for forming a field relief dielectric structure including a LOCOS layer (e.g., LOCOS layer 122 or 222) and a dielectric layer (e.g., field relief dielectric layer 124 or 224) deposited over the LOCOS layer in a microelectronic device (e.g., microelectronic device 100 or 200) are shown.

FIG. 3A shows a microelectronic device 300 including an epitaxial layer 301, a pad oxide layer 303, a dielectric layer 305, and a mask layer 307. The dielectric layer 305 may be a nitride (e.g., silicon nitride (SiN)) or oxynitride (e.g., silicon oxynitride (SiON)) material that may be etched selective to the pad oxide layer 303. The epitaxial layer 301 may be a lightly doped p-type epitaxial layer, generally representing the un-modified portion 106 or 206 in the microelectronic device 100 or 200. The mask layer 307 may be a photomask which serves to mask the dielectric layer 305. The mask layer 307 may include a light sensitive organic material that is coated, exposed and developed. Following formation of the mask layer 307, an etch process 309 is performed which removes exposed portions of the dielectric layer 305 and some or all of the underlying pad oxide layer 303 in a region where a LOCOS layer (e.g., LOCOS layer 122 or 222) will be formed.

FIG. 3B shows the microelectronic device 300 following the etch process 309. It should be noted that while FIG. 3B shows the exposed portion of the pad oxide layer 303 being fully removed as a result of the etch process 309, this is not a requirement and some amount of the pad oxide layer 303 may remain in a region exposed by the mask layer 307.

FIG. 3C shows the microelectronic device 300 following a LOCOS process (e.g., a furnace oxidation) which forms LOCOS layer 311. The LOCOS layer 311, in some examples, is very thin to result in a bird's beak shape or tapered profile without extending significantly into the underlying silicon. The LOCOS process may utilize a series of one or more dry and wet oxidation steps at temperatures ranging from about 600° C. to 1000° C., for durations in the range of about 10 minutes to 90 minutes. The durations of the dry and wet oxidation steps may be selected to form the thin LOCOS layer 311 with the bird's beak profile, which gives electric field relief in a resulting LDMOS transistor structure. Limiting the thickness of the LOCOS layer 311 may prevent significant growth into the silicon of the epitaxial layer 301, which could otherwise result in peak electric field strength below the LOCOS layer 311 that could reduce reliability of the device 300. The LOCOS layer 311 merges with the pad oxide layer 303 under the dielectric layer 305, with the bird's beak profile of the LOCOS layer 311 providing a smooth tapered transition between a maximum thickness of the LOCOS layer 311 and a minimum thickness of the LOCOS layer 311 (e.g., adjacent the pad oxide layer 303).

In some examples, the LOCOS process includes a series of oxidation steps. In contrast to typical practice, which includes at least one steam oxidation step, LOCOS layers of the disclosure may be formed using dry oxidation only as in the examples of Table I. Further, while in this example only dry oxidation steps are used, in other examples, combinations of dry and wet oxidation steps may be used, or only wet oxidation steps May be used. In some examples the oxidation may be performed in a tube furnace, for which example conditions are shown in Table I without implied limitation.

TABLE I

| | Nominal | | | | Low | | | | High | | | |
|---|---|---|---|---|---|---|---|---|---|---|---|---|
| | Time | Temp | N2 | O2 | Time | Temp | N2 | O2 | Time | Temp | N2 | O2 |
| Step | (min) | (° C.) | (SLM) | (SLM) | (min) | (° C.) | (SLM) | (SLM) | (min) | (° C.) | (SLM) | (SLM) |
| 1 | 20 | 700 | 33 | 0.27 | 18 | 630 | 26 | 0.22 | 22 | 770 | 40 | 0.32 |
| 2 | 10 | 700 | 21 | 0.15 | 9 | 630 | 17 | 0.12 | 11 | 770 | 25 | 0.18 |
| 3 | 40 | 700- | 21 | 0.15 | 36 | 630- | 17 | 0.12 | 44 | 770- | 25 | 0.18 |
| | | 900 | | | | 810 | | | | 990 | | |
| 4 | 20 | 900 | 21 | 0.15 | 18 | 810 | 17 | 0.12 | 22 | 990 | 25 | 0.18 |
| 6 | 24.5 | 900 | 6 | 25 | 22 | 810 | 4.8 | 20 | 27 | 990 | 7.2 | 30 |
| 7 | 15 | 900 | 31 | 0 | 13 | 810 | 25 | 0 | 17 | 990 | 37 | 0 |
| 8 | 70 | 900- | 21 | 0 | 63 | 630- | 17 | 0 | 77 | 770- | 25 | 0 |
| | | 700 | | | | 810 | | | | 990 | | |
| 9 | 3 | 700 | 21 | 0 | 2.7 | 630 | 17 | 0 | 3.3 | 770 | 25 | 0 |
| 10 | 20 | 700 | 33 | 0 | 18 | 630 | 26 | 0 | 22 | 770 | 40 | 0 |

FIG. 3D shows the microelectronic device 300 following deposition of a field relief material 313. The field relief material 313 may be an oxide material, a nitride material, an oxide-nitride-oxide (ONO) multi-layer, etc., which is able to be etched selective to the dielectric layer 305.

FIG. 3E shows the microelectronic device 300 following planarization of the field relief material 313, with the dielectric layer 305 providing a CMP etch stop. The LOCOS layer 311 and the planarized field relief material 313 collectively provide a field relief dielectric structure.

FIG. 3F shows the microelectronic device 300 following removal of the dielectric layer 305 using an etch process that removes the material of the dielectric layer 305 selective to that of the deposited field relief material 313, the LOCOS layer 311 and the pad oxide layer 303.

FIG. 3G shows a detailed section of the microelectronic device 300, illustrating the bird's beak profile of the LOCOS layer 311. The bird's beak profile of the LOCOS layer 311 includes a tapered portion with a distance d that extends from a thickest portion of the LOCOS layer 311 past some or all of the tapered portion of the LOCOS layer 311. The LOCOS layer 311 has a first thickness t1, and the deposited field relief material 313 has a second thickness t2, where t2 is greater than t1 (e.g., t2 may be at least twice t1).

FIG. 3H shows the microelectronic device 300 following formation of a mask layer 315 over the structure. The mask layer 315 may be formed of a photoresist material, a hard mask, etc.

FIG. 3I shows the microelectronic device 300 following patterning of the mask layer 315, such that it remains over the deposited field relief material 313.

FIG. 3J shows the microelectronic device 300 following an etch which forms tapered sidewalls in the deposited field relief material 313 below the patterned mask layer 315. This etch may be a wet etch process. Advantageously, forming the tapered sidewalls in the deposited field relief material 313 reduces corner effects which would otherwise result from the 90 degree corners at the top of the deposited field relief material 313, and provides further electric field relief. In some alternate examples a gray scale mask may be used to pattern the mask layer 315 so the sloped sidewalls are formed during the etch of the field relief material 313.

FIG. 3K shows the microelectronic device 300 following removal of the mask layer 315.

FIG. 3L shows the microelectronic device 300 following removal of the pad oxide layer 303. The pad oxide layer 303 may be removed be performing a bath in hydrofluoric acid (HF). This HF bath may remove a portion of the deposited field relief material 313, which acts as a mask protecting the underlying LOCOS layer 311 from being removed.

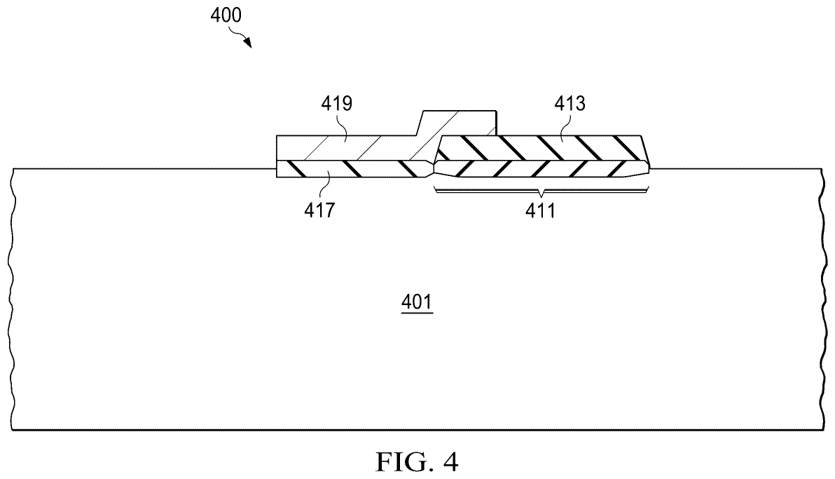

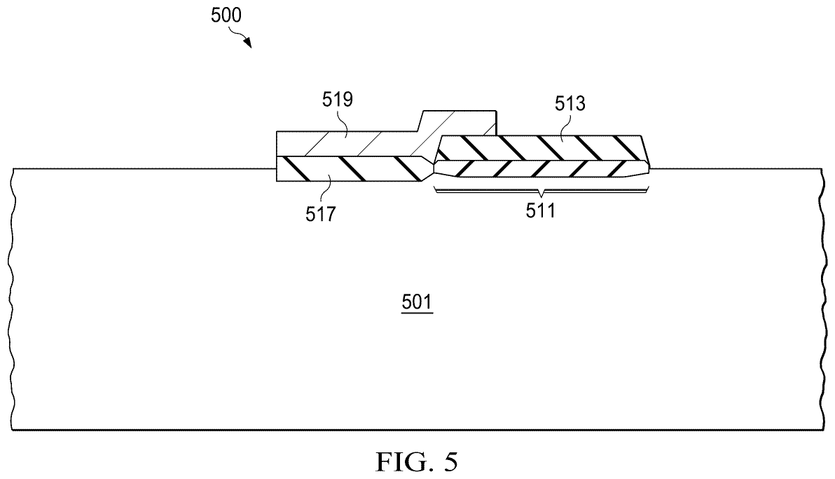

FIG. 3M shows the microelectronic device 300 following formation of gate dielectric layer 317 and gate electrode material 319. The gate dielectric layer 317 may first be formed by an oxidation process, which may be implemented by a high temperature furnace operation or a rapid thermal process. In the example of FIG. 3M, the thickness of the gate dielectric layer 317 corresponds to a thickness of the thinnest portion of the LOCOS layer 311 (e.g., the thin edge of the bird's beak profile). In other examples, as will be described in further detail below with respect to FIGS. 4 and 5, the gate dielectric layer may have a thickness that is substantially the same as the thickness of the LOCOS layer 311 or may have thickness that is greater than the maximum thickness of the LOCOS layer 311. The gate electrode material 319 is then deposited. The gate electrode material may be polysilicon, a metal, etc.

FIG. 3N shows the microelectronic device 300 following patterning of the gate electrode material 319 and the gate dielectric layer 317. This may include patterning a mask layer (not shown) over the gate electrode material 319 and removing portions of the gate electrode material 319 and the gate dielectric layer 317 exposed by the patterned mask layer. The deposited field relief material 313 has a width 321. The gate electrode material 319 is patterned to overhang or cover a portion of the deposited field relief material 313, with the amount of the overhang being width 323. The overhanging portion may be regarded as a field plate. The width 323 may vary as desired, and may range from about 20% to 100% of the width 321.

The microelectronic device 300 shown in FIG. 3N may be subject to further processing for forming an LDMOS or other transistor structure, using processing similar to that described above with respect to formation of the microelectronic device 100.

As discussed above, in the microelectronic device 300 the gate dielectric layer 317 is formed with a thickness that corresponds to a thinnest portion of the LOCOS layer 311 (e.g., an outer edge of the bird's beak profile of the LOCOS layer 311). In some examples, this provides advantages in enabling a smooth transition of the electric field profile, where the bird's beak profile of the LOCOS layer 311 provides a gradual transition in thickness between the gate dielectric layer 317 and the field relief structure (e.g., the combination of the LOCOS layer 311 and the deposited field relief material 313). In other examples, however, a gate dielectric layer may have a thickness that is substantially the same as the maximum thickness of a LOCOS layer, or may have a thickness that is greater than the maximum thickness of the LOCOS layer. These arrangements where the gate dielectric layer has a thickness that is substantially the same or greater than the maximum thickness of the LOCOS layer can provide a decrease in resistance relative to the arrangement where the gate dielectric layer has a thickness that corresponds to a thinnest portion of the LOCOS layer. These arrangements where the gate dielectric layer has a thickness that is substantially the same or greater than the maximum thickness of the LOCOS layer, however, have a risk of higher electric field points due to the topography.

Referring now to FIG. 4, a microelectronic device 400 is shown which includes an epitaxial layer 401, a LOCOS layer 411, deposited field relief material 413, gate dielectric layer 417, and gate electrode material 419. These features are analogous to those shown in the microelectronic device 300. In this example, however, the gate dielectric layer 417 has a maximum thickness that is substantially the same as the maximum thickness of the LOCOS layer 411. This can provide advantages in that that silicon “plane” (e.g., of the epitaxial layer 401) below the gate dielectric layer 417 and the LOCOS layer 411 is substantially flat, and thus may have decreased resistance relative to the example of the microelectronic device 100. The channel which carries the carriers is at the same vertical position as the highest point of the drift region. In some examples the presence of the field relief material 413 may result in the gate dielectric layer 417 including a bird's beak portion that extends from the maximum thickness of the gate dielectric layer 417 to the edge of the gate dielectric layer 417 adjacent the LOCOS layer 411. This topography may result in a high electric field point where the bird's beak profile of the LOCOS layer 411 meets the reverse bird's beak profile of the gate dielectric layer 417. In examples in which the field relief material 413 is silicon oxide, the bird's beak profile may be reduced or substantially eliminated.

Referring now to FIG. 5, a microelectronic device 500 is shown which includes an epitaxial layer 501, a LOCOS layer 511, deposited field relief material 513, gate dielectric layer 517, and gate electrode material 519. These features are analogous to those shown in the microelectronic device 300. In this example, however, the gate dielectric layer 517 has a maximum thickness that is greater than the maximum thickness of the LOCOS layer 511. This arrangement can provide decreased resistance relative to arrangements where the gate dielectric layer has a thickness that is substantially the same as the thinnest portion of the LOCOS layer, but may have an increased resistance relative to arrangements where the gate dielectric layer has a maximum thickness that is substantially the same as the maximum thickness of the LOCOS layer. Where the deposited field relief material 513 is a nitride material, the gate dielectric layer 517 may include a bird's beak portion that extends from the maximum thickness of the gate dielectric layer 517 to the edge of the gate dielectric layer 517 adjacent the LOCOS layer 511. In examples in which the field relief material 513 is silicon oxide, the bird's beak profile may be reduced or substantially eliminated.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A method of fabricating an integrated circuit, comprising:
forming a drain region in a semiconductor layer, the drain region including a drain drift region;
forming a local oxidation of silicon (LOCOS) layer over the drain drift region, the LOCOS layer having a bird's-beak region having a thickness that decreases from a maximum thickness of the LOCOS layer to a lesser thickness;
forming a field relief dielectric layer over the LOCOS layer, the field relief dielectric layer having a sloped sidewall over the bird's beak region; and
forming a gate electrode over the field relief dielectric layer.

2. The method of claim 1, wherein the field relief dielectric layer comprises silicon nitride.

3. The method of claim 1, wherein the field relief dielectric layer comprises silicon oxide.

4. The method of claim 1, wherein the field relief dielectric layer has a relative dielectric permittivity of at least 4.

5. The method of claim 1, wherein the field relief dielectric layer includes at least one oxide layer and at least one nitride layer.

6. The method of claim 1, wherein the sloped sidewall of the field relief dielectric layer meets the LOCOS layer over the bird's beak region.

7. The method of claim 1, wherein the sloped sidewall of the field relief dielectric layer forms an angle with a top surface of the semiconductor layer of no greater than 80°.

8. The method of claim 1, wherein the LOCOS layer has a first thickness and the field relief dielectric layer has a second thickness, the second thickness being at least twice the first thickness.

9. A method of fabricating a semiconductor device, comprising:
forming a source region and a drain region spaced apart in a semiconductor layer;
forming a gate dielectric layer over the semiconductor layer and extending from the source region toward the drain region; and
forming a field relief dielectric structure over the semiconductor layer and extending from the gate dielectric layer toward the drain region, the field relief dielectric structure including:
a dielectric layer; and
a local oxidation of silicon (LOCOS) layer between the dielectric layer and the semiconductor layer, the LOCOS layer extending below a top surface of the semiconductor layer by no more than 10 nanometers.

10. The method of claim 9, wherein the dielectric layer is a nitride material.

11. The method of claim 9, wherein the dielectric layer is an oxide material.

12. The method of claim 9, wherein a sidewall of the dielectric layer has a tapered profile.

13. The method of claim 9, further comprising forming a shallow trench isolation (STI) structure surrounding the semiconductor device, wherein the LOCOS layer has a thickness no greater than 10% a thickness of the STI structure.

14. The method of claim 9, wherein the semiconductor device comprises a laterally-diffused metal-oxide semiconductor (LDMOS) transistor.

15. A semiconductor device, comprising:
a source region and a drain region spaced apart in a semiconductor layer;
a gate dielectric layer on a top surface of the semiconductor layer and extending from the source region toward the drain region; and
a field relief dielectric structure over the semiconductor layer and extending from the gate dielectric layer toward the drain region, the field relief dielectric structure including:
a dielectric layer; and
a local oxidation of silicon (LOCOS) layer between the dielectric layer and the semiconductor layer, the LOCOS layer extending below a top surface of the semiconductor layer by no more than 10 nanometers.

16. The semiconductor device of claim 15, wherein the dielectric layer is a nitride material.

17. The semiconductor device of claim 15, wherein the dielectric layer is an oxide material.

18. The semiconductor device of claim 15, wherein a sidewall of the dielectric layer has a tapered profile.

19. The semiconductor device of claim 15, further comprising a shallow trench isolation (STI) structure surrounding the semiconductor device, wherein the LOCOS layer has a thickness no greater than 10% a thickness of the STI structure.

20. The semiconductor device of claim 15, wherein the semiconductor device comprises a laterally-diffused metal-oxide semiconductor (LDMOS) transistor.
